(19) United States
(12) Patent Application Publication
(10) Pub. No.: US 2002/0088545 A1
(43) Pub. Date: Jul. 11, 2002

(54) Gas injector comprising block of ceramic material having gas injection holes extending therethrough, and etching apparatus incorporating the same

(76) Inventors: Doo Won Lee, Suwon-si (KR); Tae Ryong Kim, Suwon-si (KR); No Hyun Huh, Yongin-si (KR); Chang Won Choi, Seoul (KR); Byeung-Wook Choi, Suwon-si (KR)

Correspondence Address: VOLENTINE FRANCOS, P.L.L.C., Suite 150, 12200 Sunrise Valley Drive, Reston, VA, 20191, US

(21) Appl. No.: 10/012,568

(22) Filed: Dec. 12, 2001

(30) Foreign Application Priority Data
Jan. 11, 2001 (KR) 2001-1635

(51) Int. Cl. C23F 1/00; C23C 16/00

(52) U.S. Cl. 156/345.33; 118/715

(57) ABSTRACT

A gas injector is designed to better withstand the conditions inside a semiconductor manufacturing apparatus, such as a plasma etching apparatus. The gas injector includes a body in the form of a block of ceramic material, and a gas injection section formed by first and second gas injection holes extending through the block of ceramic material. The block of ceramic material has a first cylindrical portion and a second cylindrical portion extending from the first cylindrical portion. The first cylindrical portion is wider and longer than the second cylindrical portion. The first holes of the gas injecting section extend through the first cylindrical portion of the block of ceramic material, whereas the second holes extend through the second cylindrical portion contiguously each from a respective one of the first holes and concentric therewith. The first holes are also wider and longer than the second holes. The gas injector is disposed at an upper portion of a plasma etching apparatus.

### BACKGROUND OF THE INVENTION

1. Field of the Invention

The present invention relates to a gas injector and to an etching apparatus comprising the same. More particularly, the present invention relates to a gas injector for injecting etching gas into a process chamber so as to etch films formed on a substrate and to an etching apparatus comprising such a gas injector.

2. Description of the Related Art

Recently, the semiconductor industry has made great strides as the use of information media including computers has increased. As concerns its function, a semiconductor device must operate at a high speed and have a large data storage capacity. Accordingly, improvements in semiconductor manufacturing techniques have centered around increasing the degree of integration, reliance and response speed of semiconductor devices. In this respect, etching is one of the main techniques for producing fine patterns necessary to achieve a high degree of integration for a semiconductor device. Accordingly, the etching process must conform to strict requirements.

More specifically, etching is used to pattern films formed on a semiconductor substrate. Today's semiconductor devices may have a design rule of less than 0.15 μm. Therefore, etching techniques have been developed to perform an anisotropic etching process with an etching selectivity. Plasma is mainly used to achieve the etching selectivity in the etching process. Examples of etching apparatus using plasma are disclosed in U.S. Pat. Nos. 6,013,943 and 6,004,875 issued to Cathey et. al., and U.S. Pat. No. 5,902,132 issued to Mitsuhashi.

A conventional plasma etching apparatus includes a process chamber, a gas injector, and a bias power source. One such plasma etching device is produced by the AMT Company under the model name e-MAX. The plasma etching apparatus operates as follows. A substrate is loaded into the process chamber. A gas is injected into the process chamber through a gas injector so as to form a plasma atmosphere in the process chamber. In the plasma atmosphere, films formed on the substrate are etched. The bias power source induces a bias in the substrate. Accordingly, the gas in the plasma state is attracted to the substrate while the etching process is being carried out.

Examples of conventional gas injectors are disclosed in U.S. Pat. Nos. 6,013,943 and 6,004,875 issued to Martin, and U.S. Pat. No. 6,013,155 issued to McMillin, et. al. A conventional gas injector will now be described in detail with reference to FIGS. 1 and 2.

The gas injector 10 is made of quartz and comprises a gas inlet section A and a gas outlet section B. The gas inlet section A has a hollow annular shape. The gas outlet section B has a rounded gas injecting portion 100. The gas inlet section A includes a ring-shaped portion A′ and a cylindrical portion A″. The cylindrical portion A″ has a smaller diameter than the ring-shaped portion A′. Moreover, the ratio of the axial lengths of the ring portion A′, the cylindrical portion A″ and the gas outlet section B is about 0.6: 1.5: 1.

The gas outlet B also has a plurality of holes 110 extending through the rounded gas injecting portion 100 thereof. Accordingly, the longitudinal axes of the holes 100 of the gas injector 10 subtend predetermined angles with respect to the horizontal. The holes 110 of the gas injecting portion 100 may also have various shapes. For example, U.S. Pat. No. 6,013,155 discloses a gas injector having tapered gas injecting holes.

An etching process performed by an etching device having such a gas injector will now be described with reference to FIG. 3. FIG. 3 illustrates an etching process for forming a gate spacer of a semiconductor device. The gate spacer 36 is formed at both side walls of a gate electrode 32 by a full surface etching process known as blanket etching.

More specifically, the gate electrode 32 is first formed on a substrate 30. Then, an ion implantation process is carried out using the gate electrode 32 as a mask, so that a source/drain electrode 34 is formed adjacent to the gate electrode 32 at the surface of the substrate 30. Thereafter, an oxide material is sequentially stacked on the substrate 30 and the gate electrode 32. Then, the full surface etching process is carried out by using an etching selectivity between the substrate 30 and the oxide material. Accordingly, the gate spacer 36 is formed at both side walls of the gate electrode 32.

However, particles frequently attach to the substrate 30 while the blanket etching process is being carried out. The particles interrupt the etching process and create a bridge, i.e., a fabrication defect in which the gate spacers 36 are connected to one another.

The particles mainly comprise Si, O, C and F. Among these materials, Si, C and F are elements of polymers generated when the etching process is being carried out. In addition, particles of Si and O are produced from the gas injector. That is, the gas injector is damaged by the injection gas and the bias power, applied to the substrate, when the etching process is carried out. In particular, arcing may be produced by the bias power at inner walls of the injecting portion that define the gas injecting holes. The arcing damages the gas injector to such a great extent that Si and O particles separate from the gas injector. The particles adhere to the substrate while the etching process is being carried out.

In addition, as the etching process is continuously and repeatedly carried out, the damage to the gas injector increases. The damage due to arcing is more severe within the holes of the gas injecting portion than at the surface thereof. In addition, the damage is more pronounced at the holes that are disposed further away from the longitudinal axis of the gas injector. This evidences that the degree of damage depends on the shape and material of the gas injector. In particular, the extent to which a portion of the gas injector is damaged is related to the amount of injection gases flowing through that portion of the gas injector. In addition, particles that are attached to the substrate at the outer periphery thereof are moved toward the center of the substrate because the gas injector injects gas at an angle onto the periphery of the substrate.

As mentioned above, the conventional gas injector is itself a source of particles during the conventional etching process. These particles can cause defects in the semiconductor device, whereby the reliability of semiconductor devices manufactured using the conventional plasma etching process is lowered.

### SUMMARY OF THE INVENTION

An object of the present invention is to solve the above-described problems of the prior art. Therefore, one object of the present invention is to provide a gas injector that will not begin to disintegrate during use, i.e., that will not produce particles when used to carry out a semiconductor fabrication process such as a plasma etching process.

To achieve this object, the gas injector of the present invention comprises a body in the form of a block of ceramic material, and a gas injection section formed by first and second gas injection holes extending through the block of ceramic material. The block of ceramic material has a first cylindrical portion and a second cylindrical portion extending from the first cylindrical portion. The first cylindrical portion has a first diameter and a first length, and the second cylindrical portion has a second diameter smaller than the first diameter and a second length smaller than the first length. The first holes of the gas injecting section extend through the first cylindrical portion of the block of ceramic material parallel to the longitudinal axis thereof, whereas the second holes extend through the second cylindrical portion parallel to the longitudinal axis thereof. The first holes have a third diameter and a third length, and the second holes have a fourth diameter smaller than the third diameter and a fourth length smaller than the third length The second holes each extend contiguously from a respective one of the first holes and concentric therewith.

The ratio of the second diameter to the first diameter is about 0.55-0.75: 1, and the ratio of the second length to the first length is about 0.55-0.75: 1. The ratio of the fourth diameter to the third diameter is about 0.4-0.6: 1 and the ratio of the fourth length to the third length is about 0.5-1: 1. The gas injecting section includes three to twelve pairs of the first and second holes.

The gas injector is particularly useful in a plasma etching apparatus for patterning a film formed on a substrate. In addition to at least one of the gas injectors, the etching apparatus has a process chamber in which the substrate can be supported, a source of gas used to form a plasma atmosphere in the process chamber, and a bias power source for applying a bias to the substrate so as to cause the plasma to be attracted to the substrate as the etching process is carried out.

Preferably, three gas injectors are disposed at an upper portion of the process chamber opposite the substrate. The first and second holes are oriented to extend perpendicular to the substrate and so as to vertically inject the gas towards the substrate.

### BRIEF DESCRIPTION OF THE DRAWINGS

The above and other objects, features and advantages of the present invention will become more apparent from the following detailed description of the preferred embodiments thereof made with reference to the attached drawings of which:

FIG. 1 is a perspective view of a conventional gas injector;

FIG. 2 is a sectional view taken along line II-II of FIG. 1;

FIG. 3 is a sectional view of a semiconductor device showing an etching process for forming a gate spacer using a conventional etching device;

FIG. 4 is a perspective view of a first embodiment of a gas injector according to the present invention;

FIG. 5 is a sectional view taken along line V-V of FIG. 4;

FIGS. 6 to 11 are plan views of various further embodiments of gas injectors according to the present invention;

FIG. 12 is a schematic diagram of an etching apparatus according to the present invention; and

FIG. 13 is a graph showing the number of particles produced when etching processes are carried out using the etching device according to the present invention.

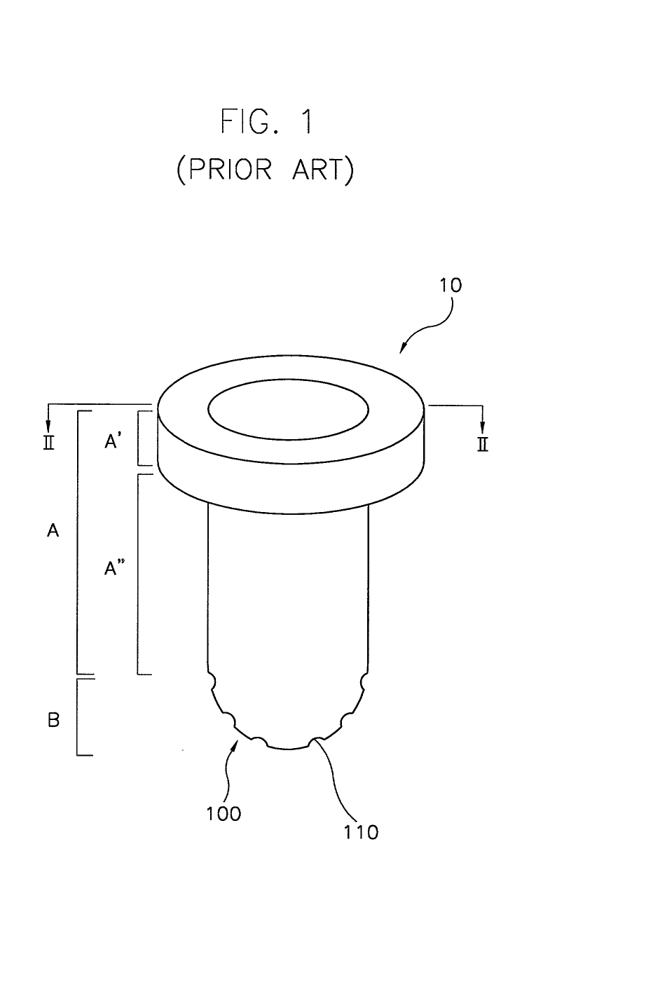

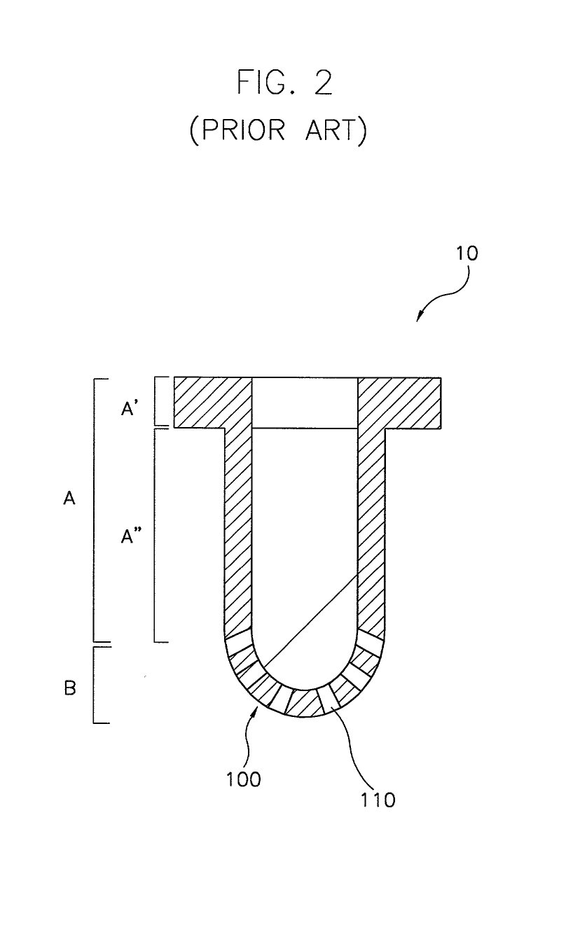

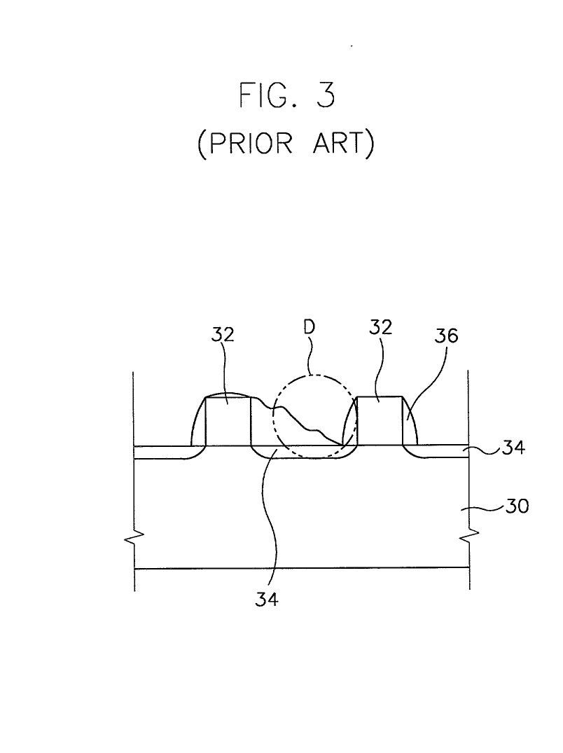

### DETAILED DESCRIPTION OF THE PREFERRED EMBODIMENTS

Hereinafter, preferred embodiments of the present invention will be described in detail with reference to accompanying drawings.

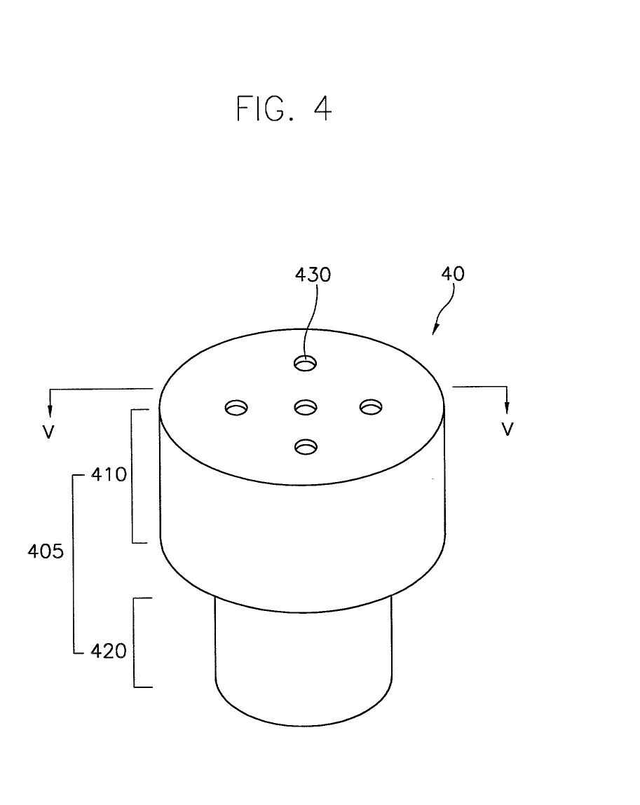

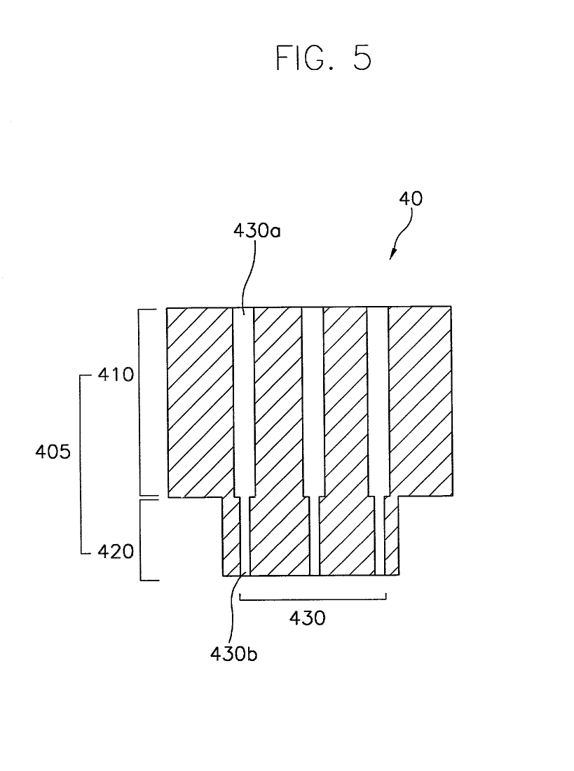

Referring first to FIGS. 4 and 5, the gas injector 40 includes a body 405 and a gas injecting section 430. The gas injecting section 430 defines a gas passage through the body 405.

The body 405 is a block of ceramic material having a first cylindrical portion 410 and a second cylindrical portion 420. The second cylindrical portion 420 extends continuously from the first cylindrical portion 410. That is, the first cylindrical portion 410 and the second cylindrical portion 420 are integral. The first cylindrical portion 410 serves as a gas inlet, whereas the second cylindrical portion 420, therefore, serves as a gas outlet. The diameter (hereinafter “second diameter”) of the second cylindrical portion 420 is smaller than the diameter (hereinafter “first diameter”) of the first cylindrical portion 410, and the length (hereinafter “second length”) of the second cylindrical portion 420 is smaller than the length (hereinafter “first length”) of the first cylindrical portion 410. Specifically, the ratio of the second diameter to the first diameter is about 0.55-0.75: 1, and the ratio of the second length tot he first length is also about 0.55-0.75: 1.

The gas injecting section 430 includes first holes 430a and second holes 430b. Preferably, the gas injecting section 430 includes three to twelve first and second holes. The first holes 430a extend through the first cylindrical portion 410 and the second holes 430b extend through the second cylindrical portion 420. That is, the first holes 430a form the gas inlet and the second holes 430b form the gas outlet. The gas injecting section 430 has a diameter limited by the diameter of the second cylindrical 420. The second holes 430b have a length (hereinafter “fourth length”) that is smaller than the length (hereinafter “third length”) of the first holes 430a. In addition, the diameter of the second holes 430b (hereinafter “fourth diameter”) is smaller than the diameter (hereinafter “third diameter”) of the first holes 30a. Specifically, the ratio of the fourth diameter to the third diameter is about 0.4-0.6: 1, and the ratio of the fourth length to the third length is 0.5-1: 1.

The first holes 430a and the second holes 430b are concentric. Therefore, central axes of the first holes 430a and the second holes 430b are coincident. In addition, the first holes 430a and the second holes 430b are extend parallel to the longitudinal axes of the first and second cylindrical portions 410 and 420, respectively. Accordingly, the gas injector 40 can inject gas vertically.

In a preferred embodiment of the present invention, the diameter of the first cylindrical portion 410 is about 17 to 21 mm and the diameter of the second cylindrical portion 420 is about 10.2 to 14.7 mm. In addition, the length of the first cylindrical portion 410 is about 3.8 to 4.6 mm and the length of the second cylindrical portion 420 is about 2.3 to 3.2 mm. The diameter of the first holes 430a is about 1.8 to 2.2 mm and the diameter of the second holes 430b is about 0.72 to 1.32 mm. In addition, the axial length of the first holes 430a is about 3.1 to 5.2 mm and the axial length of the second holes 430b is about 2.1 to 3.9 mm.

In practical embodiment used in the field, the diameter of the first cylindrical portion 410 is 19 mm, the length of the first cylindrical portion 410 is 4.2 mm, the diameter of the second cylindrical portion 420 is 12.6 mm, the length of the second cylindrical portion 420 is 2.8 mm, the diameter of the first holes 430a is 2 mm, the axial length of the first holes 430a is 4.2 mm, the diameter of the second holes 430b is 1 mm and the axial length of the second holes 430b is 2.8 mm.

In addition, the gas injector 430 is made of a ceramic material. In this regard, alumina (Al₂O₃) having a purity of greater than 99% is used. The ceramic is a refractory material having superior resistance to heat and corrosion. Accordingly, the gas injector 430 can withstand the prevailing environment during its use, namely can withstand the effects of the injection gas and arcing.

The gas injector has a cylindrical body but is a solid block and is not in the form of a hollow shell. Hence, the gas injector is not readily damaged. In addition, particles attached to periphery of the substrate will not be moved towards an inner portion of the substrate because the injection gas is vertically injected onto the substrate. Furthermore, the speed of the injection gas is increased as the injection gas flows through the second holes 430b because the sectional areas of the second holes 430b are smaller than the sectional areas of the first holes 430a. Therefore, the contact time between the injection gas and the walls defining the second holes 430b is minimized. In addition, the diameters of the first and second holes 430a and 430b are different from one another, whereby arcing into the first holes 430a is suppressed. Also, the gas injector is not easily damaged by the injection gas and the arcing because the gas injector is fabricated of a corrosion-proof material.

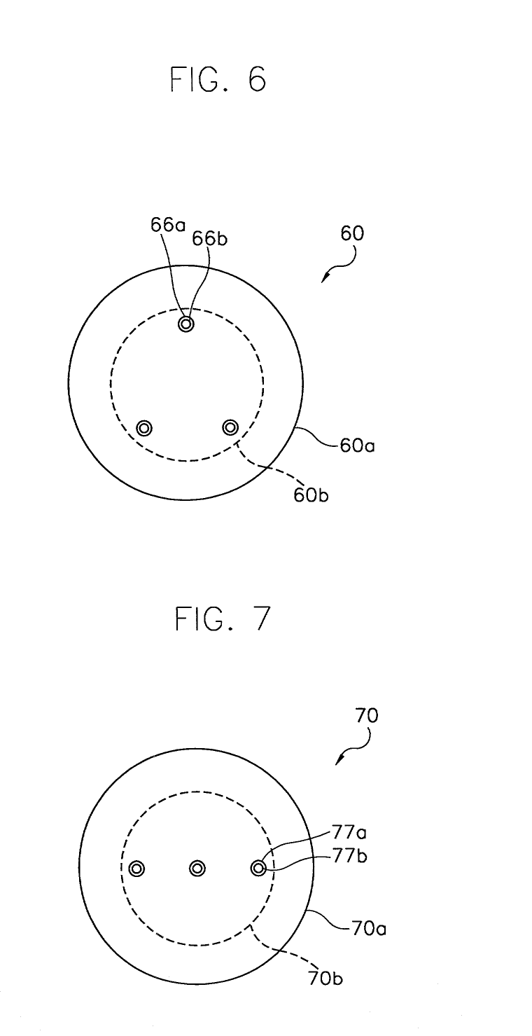

Various embodiments of gas injectors according to the present invention will now be described with reference to FIGS. 6 to 11.

Referring now to FIG. 6, a gas injector 60 has a first cylindrical portion 60a and a second cylindrical portion 60b. In addition, three first holes 66a and three second holes 66b form the gas injecting section of the gas injector 60. The three pairs of corresponding first and second holes 66a and 66b are arranged in a triangular pattern in which a central axis of each pair of first and second holes 66a and 66b is located at a respective vertex of a triangle.

Referring to FIG. 7, a gas injector 70 includes a first cylindrical portion 70a and a second cylindrical portion 70b. In addition, three first holes 77a and three second holes 77b form the gas injecting section of the gas injector 70. The three pairs of corresponding first and second holes 66a and 66b are arranged in line with each other along a transverse axis of the gas injector 70.

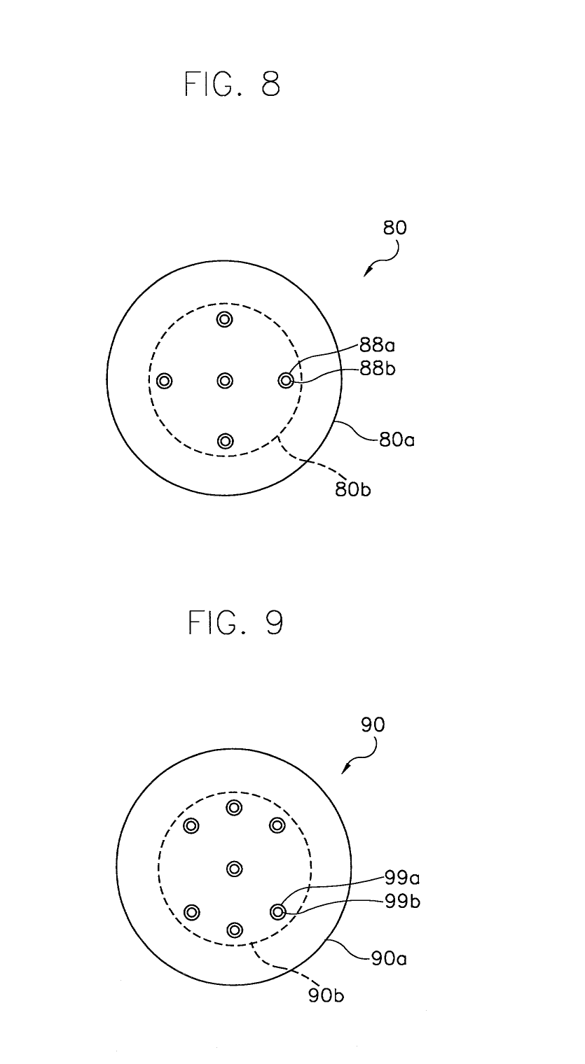

Referring to FIG. 8, a gas injector 80 includes a first cylindrical portion 80a and a second cylindrical portion 80b. In addition, five first holes 88a and five second holes 88b form the gas injecting section of the gas injector 80. The five pairs of corresponding first and second holes 88a and 88b are arranged in a rectangular pattern in which the central axes of four of the pairs of (first and second) holes are located at the corners of a rectangle and the central axes of the fifth pair of (the first and second) holes are located at the center of the rectangle.

Referring to FIG. 9, a gas injector 90 includes a first cylindrical portion 90a and a second cylindrical portion 90b. In addition, seven first holes 99a and seven second holes 99b form the gas injecting section of the gas injector 90. The seven corresponding pairs of first and second holes 99a and 99b are arranged in a hexagonal pattern in which central axes of six of the pairs of (first and second) holes 99a and 99b are located at vertices of a hexagon and the central axes of the remaining corresponding pair of (first and second) holes is located at the center of the hexagon.

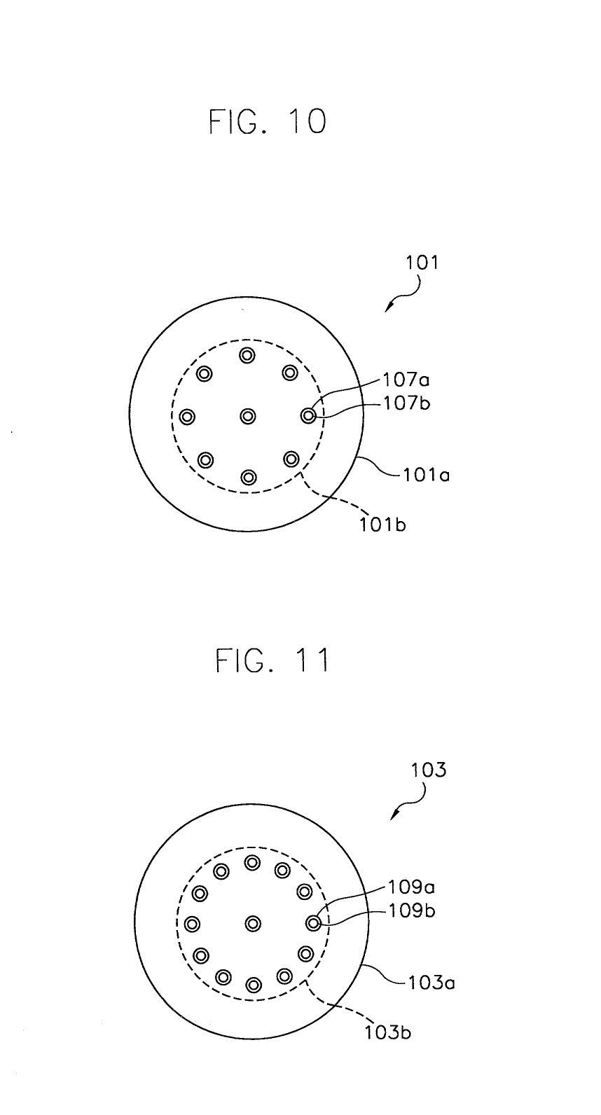

Referring to FIG. 10, a gas injector 101 includes a first cylindrical portion 101a and a second cylindrical portion 101b. In addition, nine first holes 107a and nine second holes 107b form a gas injecting section of the gas injector 101. The nine pairs of corresponding first and second holes 107a and 107b are arranged in an octagonal pattern in which the central axes of eight pairs of the first and second holes 107a and 107b are located at vertices of an octagon and a the central axes of the remaining pair of (first and second) holes is located at a center of the octagon.

Referring to FIG. 11, a gas injector 103 includes a first cylindrical portion 103a and a second cylindrical portion 103b. In addition, twelve first holes 109a and twelve second holes 109b form the gas injecting section of the gas injector 103. Eleven pairs of the first and second holes 109a and 109b are arranged in a circle. The central axes of the remaining pair of first and second holes 109a and 109b is located at the center of the circle.

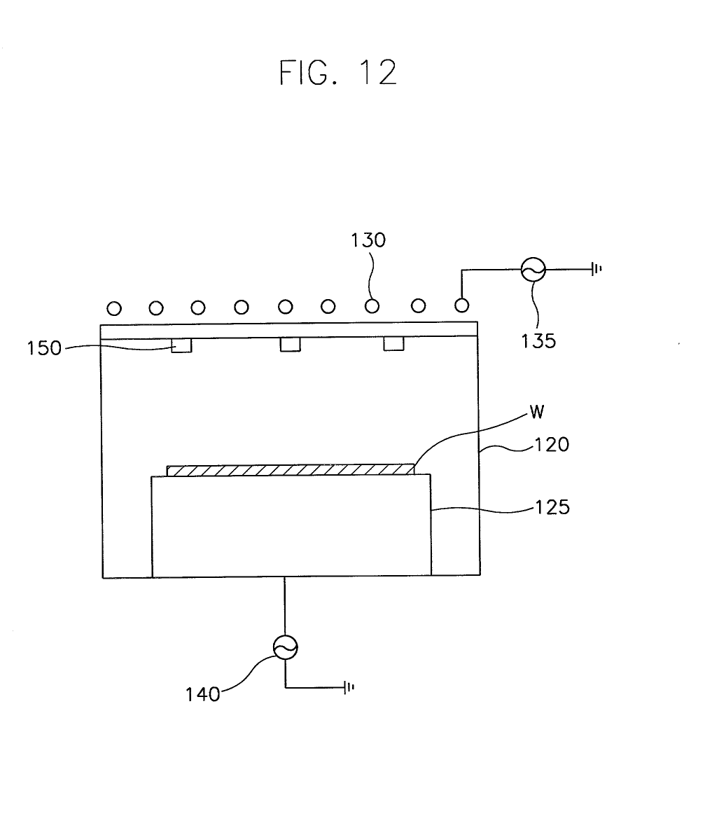

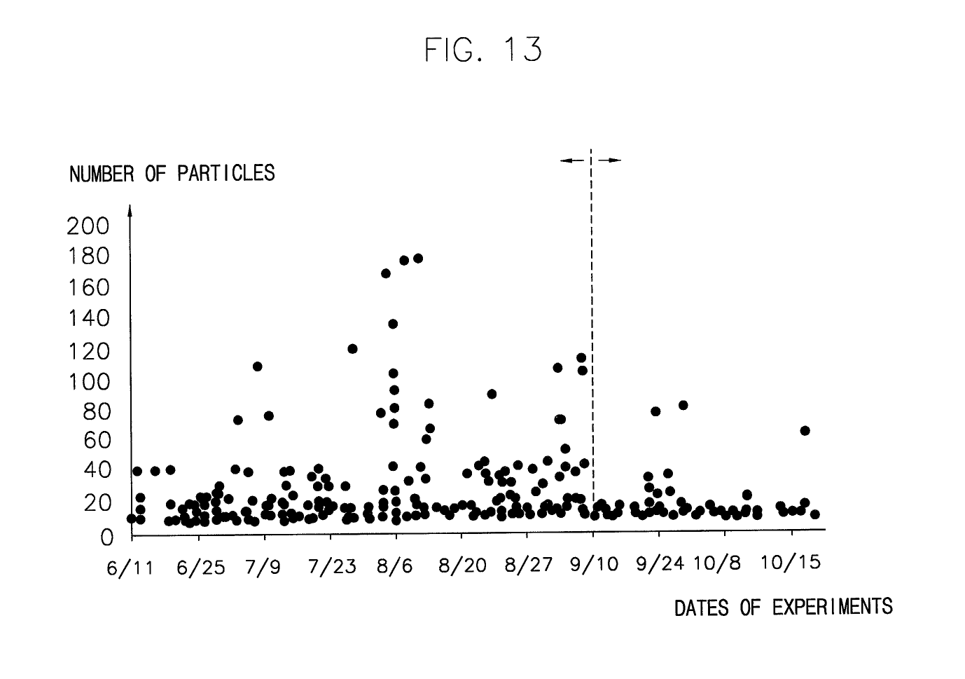

Next, an etching apparatus comprising the gas injector will be described with reference to FIG. 12. The etching apparatus shown in FIG. 12 generates plasma using a TCP (transformer coupled plasma) technique.

Referring to FIG. 12, the etching apparatus comprises a process chamber 120, gas injectors 150 and a bias power supply 140. In addition, the etching apparatus includes a coil 130 for transmitting power at a radio frequency into the process chamber 120, a plasma power source 135 for supplying electric power to the coil 130, a chuck 125 disposed in the process chamber 120 so as to support a substrate W, and a valve device (not shown) which is openable/closable to allow the substrate W to be transferred/withdrawn into/from the process chamber 120. The valve device includes a needle valve.

The process chamber 120 having the substrate W therein receives gas so as to form a plasma atmosphere in the process chamber 120. In the plasma atmosphere, a film formed on the substrate W is etched so that patterns are formed on the substrate. The bias power supply 140 applies a bias power to the substrate W so as to cause the plasma to be attracted towards the substrate W when the etching process is carried out. Accordingly, the plasma has a directional feature when the etching process is carried out.

Three of the gas injectors 150 are disposed at an upper portion of the process chamber 120 as spaced from each other by equal intervals. Accordingly, the gas injectors 150 oppose the substrate W and inject the gas vertically onto the substrate W through the first and second holes which extend perpendicular to the substrate W. As mentioned before, for each gas injector 150, the ratio of the second diameter to the first diameter is about 0.55-0.75: 1 and the ratio of the second length to the first length is about 0.55-0.75: 1. The ratio of the fourth diameter to the third diameter is about 0.4-0.6: 1 and the ratio of the fourth length to the third length is about 0.5-1: 1.

The inventors of the present invention conducted experiments for forming a gate spacer using the etching apparatus having gas injectors of the type described above as the practical embodiment. The results of these experiments showed that the present invention produced comparatively few particles. FIG. 13 is a graph showing the number of particles measured when the etching process was carried out using the etching apparatus according to the present invention.

In FIG. 13, the X-axis represents the dates of experiments and the Y-axis represents the number of particles. The conventional etching apparatus was used on the dates prior to Sep. 10, 2000, whereas the etching apparatus according to the present invention was used on the dates on and after September 10.

In these experiments, the number of particles was measured after cleaning the substrate with an SC1 solution (a mixed solution of H₂O:H₂O₂ (30%):NH₄ OH(29%)=5:1:1) such as KLA (trade name manufactured by KLA-Tencor Technologies Co., Ltd.). An electric power of 600 Watts was applied.

As shown in the graph, the number of particles was remarkably reduced when the etching process was carried out using the etching apparatus according to the present invention. In particular, the average number of particles was 14.7 when using the conventional etching apparatus. However, the average number of particles was only 5.8 when using the etching apparatus according to the present invention.

The inventors of the present invention also found that the particles produced when using the present invention were of the type that make up the polymer which is generated during the etching process. Accordingly, it can be deemed that particles are not produced from the gas injector when the etching process is carried out using the etching apparatus according to the present invention.

In summary, because the gas injector of the present invention is made of a ceramic material, the gas injector can withstand the effects of the injection gas and the arcing so that the gas injector does not begin to disintegrate and produce particles. In addition, because the gas injector comprises a solid block of material having gas injection holes extending therethrough, the contact area between the gas and the gas injector is minimal so that the damage to the gas injector is correspondingly limited. Furthermore, the holes formed in the cylindrical gas injector are designed to reduce the contact time between the injection gas and the injector, so that the damage to the gas injector is correspondingly limited. When arcing is produced by the bias power applied to the substrate, the arcing gas hardly penetrates into the holes, whereby damage to the gas injector is prevented. In addition, because the holes are oriented perpendicular to the substrate, the injection gas passing through the holes of the gas injector is injected vertically onto the substrate. Therefore, particles, such as particles of polymer attached to periphery areas of the substrate, will not be blown towards the center of the substrate.

Accordingly, an etching apparatus of the present invention can be operated with an electric power above 500 Watts and at a pressure below 20 mTorr. Preferably, the etching apparatus is operated with an electric power of greater than 1500 watts and at a pressure of less than 15 mTorr, which parameters are necessary to meet current requirements for fabricating fine patterns. In addition to performing the full surface etching process for forming the gate spacer, the etching apparatus of the present invention can be adapted to perform the partial etching process for forming a contact hole.

As mentioned above, according to the present invention, the gas injector is not itself a source of particles that otherwise produce defects in the semiconductor device. In addition, the present invention can keep maintenance and repairing costs under control as the gas injector is hardly prone to becoming damaged.

Finally, although the present invention has been described in detail with reference to the preferred embodiments thereof, various changes, substitutions and alterations can be made thereto. For instance, although the gas injector has been described above with reference to several embodiments having between three and twelve pairs of first and second holes, the present invention is not so limited to having such numbers of gas injection holes. Accordingly, the true spirit of the invention is seen to encompass all such changes, substitutions and alterations as come within the scope of the appended claims.

What is claimed is:

1. A gas injector comprising:
a block of ceramic material, the block having a first cylindrical portion and a second cylindrical portion extending from the first cylindrical portion, the outer diameter of the second cylindrical portion being smaller than that of the first cylindrical portion, and the length of the second cylindrical portion being smaller than that of the first cylindrical portion; and
a gas injecting section including first holes extending through the first cylindrical portion of said block of ceramic material and second holes extending through the second cylindrical portion of said block, the second holes having a diameter smaller than that of the first holes, and the second holes having an axial length shorter than that of the first holes, each of the second holes extending from a respective one of the first holes and concentric therewith.

2. The gas injector as claimed in claim 1, wherein the outer diameter of the second cylindrical portion is about 0.55-0.75 that of the first cylindrical portion, and the length of the second cylindrical portion is about 0.55-0.75 that of the first cylindrical portion.

3. The gas injector as claimed in claim 2, wherein the outer diameter of the first cylindrical portion is about 17 to 21 mm, the outer diameter of the second cylindrical portion is about 10.2 to 14.7 mm, the length of the first cylindrical portion is about 3.8 to 4.6 mm, and the length of the second cylindrical portion is about 2.3 to 3.2 mm.

4. The gas injector as claimed in claim 1, wherein the diameter of the second holes is about 0.4-0.6 that of the first holes, and the axial length of the second holes is about 0.5-1 that of the first holes.

5. The gas injector as claimed in claim 4, wherein the diameter of the first holes is about 1.8 to 2.2 mm, the diameter of the second holes is about 0.72 to 1.32 mm, the axial length of the first holes is about 3.1 to 5.2 mm and the axial length of the second holes is about 2.1 to 3.9 mm.

6. The gas injector as claimed in claim 1, wherein the gas injecting section includes three to twelve pairs of said first and second holes.

7. The gas injector as claimed in claim 6, wherein the gas injecting section includes three pairs of corresponding first and second holes, the three pairs of first and second holes being arranged in a triangle pattern in which the central axes of each pair of first and second holes is located at a respective vertex of a triangle.

8. The gas injector as claimed in claim 6, wherein the gas injecting section includes five pairs of corresponding first and second holes, and the five pairs of first and second holes being arranged in a rectangular pattern in which the central axes of four of the pairs of first and second holes are located at vertices of a rectangle and the central axes of a fifth pair of the first and second holes is located at the center of the rectangle.

9. The gas injector as claimed in claim 6, wherein the gas injecting section includes nine pairs of corresponding first and second holes, the nine pairs of first and second holes being arranged in an octagonal pattern in which the central axes of eight pairs of the first and second holes are located at the vertices of an octagon, respectively, and the central axes of a ninth pair of the first and second holes are located at the center of the octagon.

10. The gas injector as claimed in claim 1, wherein the first and second holes extend parallel to the axial directions of the first and second cylindrical portions, respectively.

11. An etching apparatus comprising:
a process chamber for receiving a substrate therein;
at least one gas injector by which gas is injected into the process chamber, the gas injector including a block of ceramic material, the block having a first cylindrical portion and a second cylindrical portion extending from the first cylindrical portion, the outer diameter of the second cylindrical portion being smaller than that of the first cylindrical portion, and the length of the second cylindrical portion being smaller than that of the first cylindrical portion, and
a gas injecting section including first holes extending through the first cylindrical portion of said block of ceramic material and second holes extending through the second cylindrical portion of said block, the second holes having a diameter smaller than that of the first holes, and the second holes having an axial length shorter than that of the first holes, each of the second holes extending from a respective one of the first holes and concentric therewith; and
a bias power supply for applying a bias power to a substrate supported in the process chamber.

12. The etching apparatus as claimed in claim 11, wherein three of said gas injectors are disposed in the process chamber.

13. The etching apparatus as claimed in claim 11, wherein said at least one gas injector is disposed at an upper portion of the process chamber.

14. The etching apparatus as claimed of claim 11, wherein the outer diameter of the second cylindrical portion is about 0.55-0.75 that of the first cylindrical portion, and the length of the second cylindrical portion is about 0.55-0.75 that of the first cylindrical portion.

15. The etching device as claimed in claim 14, wherein the outer diameter of the first cylindrical portion is about 17 to 21 mm, the outer diameter of the second cylindrical portion is about 10.2 to 14.7 mm, the length of the first cylindrical portion is about 3.8 to 4.6 mm, and the length of the second cylindrical portion is about 2.3 to 3.2 mm.

16. The etching device as claimed in claim 11, wherein the diameter of the second holes is about 0.4-0.6 that of the first holes, and the axial length of the second holes is about 0.5-1 that of the first holes.

17. The etching device as claimed in claim 16, wherein the diameter of the first holes is about 1.8 to 2.2 mm, the diameter of the second holes is about 0.72 to 1.32 mm, the axial length of the first holes is about 3.1 to 5.2 mm and the axial length of the second holes is about 2.1 to 3.9 mm.

18. The etching device as claimed in claim 11, wherein the first and second holes extend vertically in the process chamber.
